(19) United States
(12) Patent Application Publication
(10) Pub. No.: US 2006/0091295 A1
(43) Pub. Date: May 4, 2006

(54) System to illuminate an enclosure

(76) Inventor: Peter Ethan Staples, Los Angeles, CA (US)

Correspondence Address: SCHOX PLC, 209 N. MAIN STREET #200, ANN ARBOR, MI, 48104, US

(21) Appl. No.: 11/260,777

(22) Filed: Oct. 27, 2005

Related U.S. Application Data
(60) Provisional application No. 60/625,409, filed on Nov. 4, 2004.

(51) Int. Cl. H03K 17/78; G06M 7/00; H01J 40/14

(52) U.S. Cl. 250/214 SW; 250/221

(57) ABSTRACT

The system 10 of the preferred embodiment includes a sensor 12 to detect the status of an enclosure, a light source 14 to illuminate the enclosure, a power source 16, a circuit board 18, a housing element 20, and a fastener 22. The system 10 of the preferred embodiment has been specifically designed to detect the opening of a drawer, a door, or a lid of an enclosure and to illuminate the interior of the enclosure.

### CROSS-REFERENCE TO RELATED APPLICATIONS

This application claims the benefit of U.S. Provisional Application No. 60/625,409, entitled “System to Illuminate an Enclosure”, and filed 4 Nov. 2004, which is incorporated in its entirety by this reference.

### BRIEF DESCRIPTION OF THE FIGURES

FIGS. 1-3 are perspective, side, and expanded views, respectively, of the preferred embodiment.

FIGS. 4 and 5 are two variations of the housing of the preferred embodiments.

FIGS. 6 and 7 are side and perspective views, respectively, of an alternative embodiment.

FIG. 8 is circuit diagram of a slow turn-on and/or a slow turn-off circuit of an alternative embodiment.

### DESCRIPTION OF THE PREFERRED EMBODIMENTS

The following description of the preferred embodiments of the invention is not intended to limit the invention to these preferred embodiments, but rather to enable any person skilled in the art to make and use this invention.

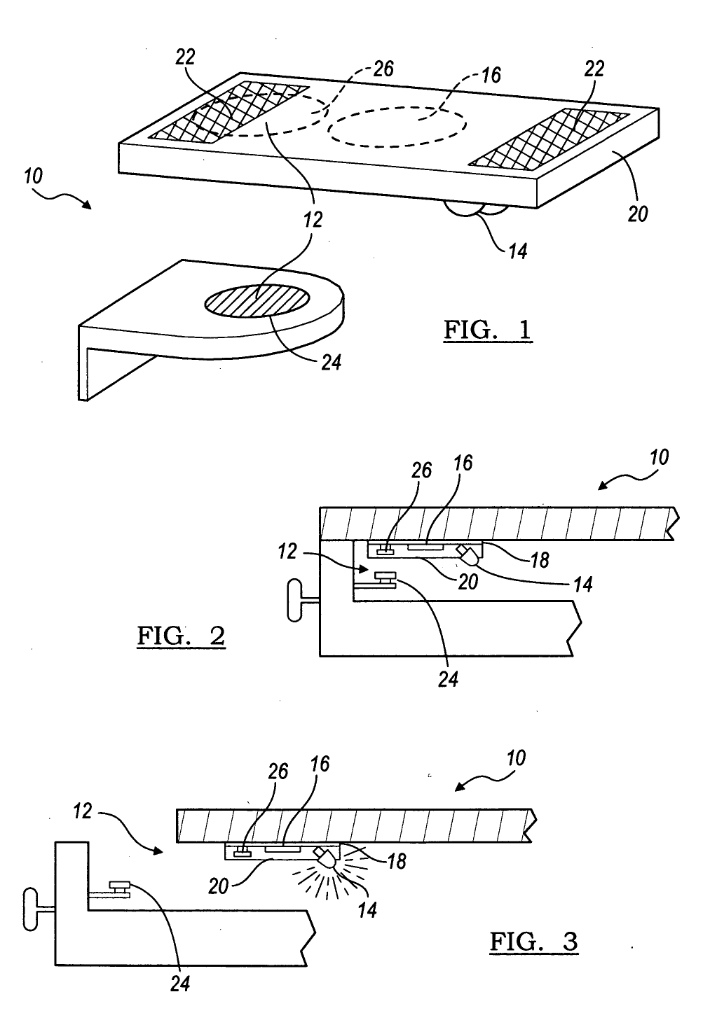

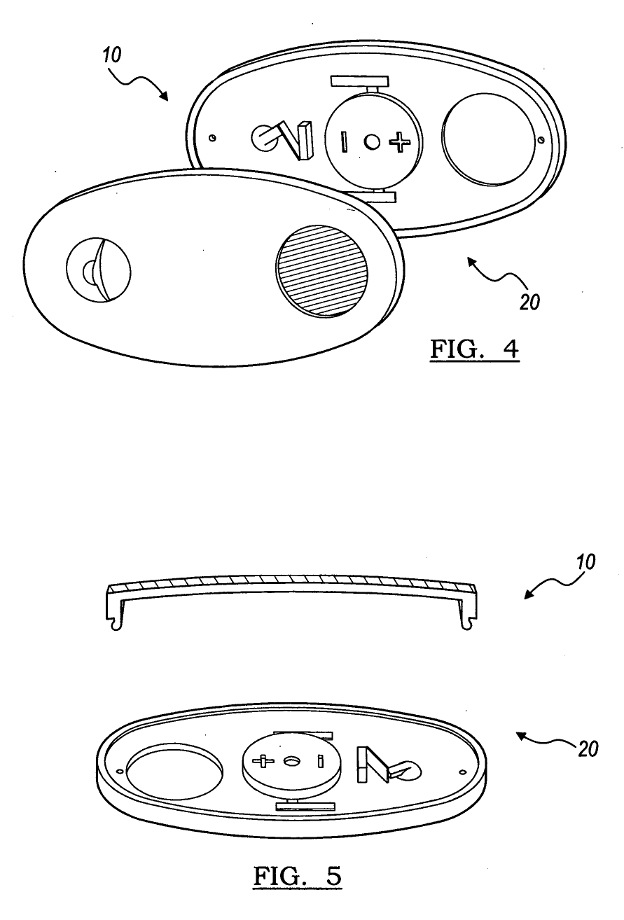

As shown in FIGS. 1, 2, and 3, the system 10 of the preferred embodiment includes a sensor 12 to detect the status of an enclosure, a light source 14 to illuminate the enclosure, a power source 16, a circuit board 18, a housing element 20, and a fastener 22. The system 10 of the preferred embodiment has been specifically designed to detect the opening of a drawer, a door, or a lid of an enclosure and to illuminate the interior of the enclosure. The system 10, however, may be used in any suitable environment and for any suitable reason.

The sensor 12 of the preferred embodiment functions to detect the opened or closed status of the enclosure and to control a switch. The switch functions to connect the power source 16 and the light source 14 (thereby turning the light source 14 on) when the enclosure is open, and to disconnect the power source 16 and the light source 14 (thereby turning the light source 14 off) when the enclosure is closed.

In a first variation, the sensor 12 is a magnetic sensor, including a magnet 24 and a magnet-sensing device 26. The magnet 24 is preferably fixed to the drawer, door, or lid of the enclosure, while the magnet-sensing device 26 is preferably fixed to the circuit board 18 of the system 10 and ultimately placed within the enclosure. The magnet 24 and the magnet-sensing device 26 may, however, be located in any suitable location, including in a remote location from the circuit board with either a wired or wireless connection. The magnet-sensing device 26 is preferably a Hall-effect sensor, but may be a magnetic contact switch (e.g., a reed switch) or any suitable magnetic sensor. The magnet-sensing device 26 preferably opens the switch upon the close proximity of the magnet 24 and closes the switch upon the withdrawal of the magnet 24 (which would occur, for instance, upon the opening of the drawer, door, or lid of the enclosure). In this manner, the magnetic sensor is able to detect the opened or closed status of the enclosure.

In a second variation, the sensor 12 is an IR sensor (such as certain motion detectors) that detects the motion of the drawer, door, or lid of the enclosure. By detecting this motion, the IR sensor estimates the opened or closed status of the enclosure. The IR sensor preferably includes a suitable IR emitter/detector pair in any suitable configuration. In a third variation, the sensor 12 is a pressure sensor (such as a scale) that detects the increase or decrease in pressure caused by the motion of the drawer, door, or lid of the enclosure. By detecting the pressure change, the pressure sensor estimates the opened or closed status of the enclosure. In a fourth variation, the sensor 12 is a photo-conductor (such as a light detector) that detects the increase in light intensity caused by the opening of the drawer, door, or lid of the enclosure. By detecting the light intensity change, the photo-conductor estimates the opened or closed status of the enclosure. In a fifth variation, the sensor 12 is a mechanical switch that is depressed when the enclosure is closed and released upon the opening of the enclosure. Although the sensor 12 is preferably one of these five variations, the sensor 12 may be any suitable device or method to detect the opened or closed status of the enclosure and thereby control the switch.

The light source 14 of the preferred embodiment functions to illuminate the enclosure and to facilitate visibility into the enclosure. The light source 14 is preferably an LED, but may alternatively be any suitable light emitting element, such as conventional incandescent light bulbs or organic light emitting devices (also known as OLEDs). The light source 14 is preferably manufactured and placed directly on the circuit board 18, but may alternatively be manufactured with any suitable process and may be located in any suitable location (including being located in a remote location).

The power source 16 of the preferred embodiment functions to power each element within the system 10 requiring power. In a first variation, the power source 16 is a battery. The battery is preferably a small, flat battery such as a coin (or button) cell battery attached to the circuit board 18, but may alternatively be any suitable battery. In a second variation, the power source 16 is preferably a power cord that attaches to the power grid of the building in which the enclosure is located.

The circuit board 18 of the first embodiment functions as a base for the other elements. The circuit board 18 is preferably rectangular and planar. The circuit board 18 may, however, be any suitable shape. The circuit board 18 is preferably rigid, but may alternatively be partially or completely flexible. The circuit board 18 is preferably made of a conventional epoxy and fiberglass composition and with conventional manufacturing processes, but may alternatively be made of any suitable material and with any suitable manufacturing process.

The housing element 20 functions to protect and contain many, if not all, of the elements of the system 10 . The housing element 20 is preferably a very low profile design, somewhat similar to the shape of a stick of gum. The low profile design allows the system 10 to occupy a minimal amount of volume in the enclosure and to minimize the potential that the housing element 20 would catch on or move the contents of the enclosure. Preferably, the aspect ratio of the housing element 20 is approximately a 10 to 1 ratio (the thickness is one tenth of the length). Alternatively, the aspect ratio may be thinner or thicker depending on the planned use of the system 10.

The housing element 20 of the preferred embodiment is preferably one of several variations but may consist of any suitable device or method by which to protect and contain the elements of the system 10. In a first variation, as shown in FIG. 4, the housing element 20 is a two-part snap fit housing, which snaps closed around the elements of the system 10. This variation is preferably made of plastic or rubber, but alternatively may be made of any suitable material. In a second variation, as shown in FIG. 5, the housing element 20 is a one part snap fit and an adhesive strip on a rigid or semi-rigid bar. In this variation, the elements of the system 10 are placed into the snap fit part. The adhesive strip is then snapped into this part, holding the elements in place. This variation is preferably made of plastic or rubber, but alternatively may be made of any suitable material. The housing element 20 of these first two variations functions to ease removal and reinstallation of the device, which will provide access for maintenance or replacement without the inconvenience of reinstalling a new system.

In a third variation, the housing element 20 is a protective coating or shell on the back of the circuit board 18 element that is then snapped into a lid element. The coating is preferably a durable plastic, rubber, or metal, but may alternatively be made of any suitable material. The lid element may be made of any durable material that is compatible with the protective coating on the circuit board 18. In a fourth variation, the housing element 20 consists of a protective coating or shell over the entire circuit board 18 and the contents of the system 10 . The coating is preferably a durable plastic, rubber, or metal, but may alternatively be made of any suitable material.

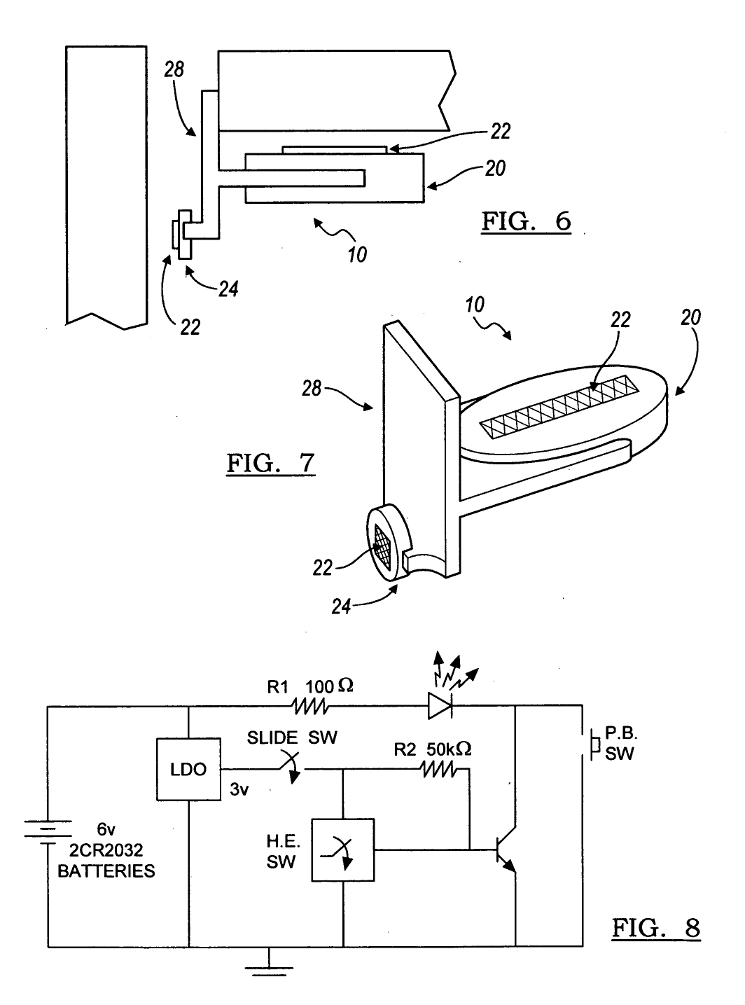

As shown in FIGS. 6 and 7, the housing element 20 of the preferred embodiment may also include an installation guide element 28. As described, the sensor 12 of the preferred embodiment consists of a magnet 24, which is fixed to the door or lid of the enclosure, and a magnet-sensing device 26, which is fixed to the circuit board 18 of the system 10. During the installation of the invention, it may be challenging for a user to correctly align these two pieces. The installation guide element 28 functions to ensure proper installation and operation of the system 10 .

In a first variation, the installation guide element 28 is a perforated piece of material that connects the magnet 24 and the housing element 20. With the installation guide element 28, the system 10 may then be installed in the enclosure as one unit and upon adhesion, the perforated material connecting the two pieces may be snapped, cut, or simply break away upon the first opening of the drawer. The installation guide element 28 is preferably plastic, but may alternatively be any material that can be separated when desired by the user. In a second variation, the installation guide element 28 includes guideposts on the magnet 24 of the sensor 12 and receiving holes in the adjacent housing element 20 (or vice versa). The guideposts and the receiving holes ensure correct alignment of the magnet 24 with the magnet-sensing device 26 during both installation and use. The guideposts are preferably made of durable plastic, but may alternatively be made of any suitable material. In a third variation, the installation guide element includes a cutaway or molded slot portion of the housing that will fit over the magnet 24 of the sensor 12. This will guide the housing over the magnet 24 in the correct alignment and will ensure correct installation. Although the installation guide element 28 preferably includes one of these three variations, the installation guide element 28 may alternatively include any suitable device or method to help the user correctly install the two pieces of the system l0.

The fastener 22 of the preferred embodiment functions to fix the housing element 20 within the enclosure. The fastener 22 is preferably attached to a portion of the housing element 20 and attached to the separate magnet 24 of the system l0. The fastener 22 is preferably made of two sided adhesive, but may alternatively be made of any suitable material to affix the housing element 20 within the enclosure. Such variations include providing holes in the housing suitable for screws or nails or providing VELCRO fasteners, suction cups, snaps, or any other suitable device or method to affix the housing element 20 within the enclosure.

The system l0 of the preferred embodiment may also include a wireless device. The wireless device to connect the sensor 12 and the light source 14, to connect the system 10 to another adjacent system 10, or may function to connect the system 10 to a larger network, such as a ZigBee network, a Bluetooth network, or an Internet-protocol based network. In one variation, the sensor 12 transmits a radio frequency (RF) signal and a receiver receives the RF signal. In another variation, the sensor 12 transmits a signal over a network (possibly a wireless local access network or the internet using an internet protocol address) and a receiver receives the signal.

The system 10 of the preferred embodiment may also include a timing mechanism. In the instance where an enclosure is left open, the system 10 will remain on and the power source 16 may be unnecessarily drained. The timing mechanism functions to shut the system 10 off after a predetermined length of time so that the system 10 will not be inadvertently left on and the power source 16 will not be unnecessarily drained. In the sensor 12 variations two, three, and four or by any means in which the sensor 12 responds to the occurrence of an event, a timing mechanism may be required to turn the light source 14 off after a predetermined length of time.

The system 10 of the preferred embodiment may also include a slow turn-on and/or a slow turn-off circuit, as shown in FIG. 8. These circuits function to provide feedback to the user of the system 10 and allow the user to visually experience the light source 14 turning on. With this feedback, the user can be assured that the power source 16 is not always on.

The system 10 of the preferred embodiment may further include a sound alert system. The sound alert system functions to alert the user when the enclosure has been opened. This feature may be useful to alert the user when the enclosure has been opened by an unauthorized user or a small child. Furthermore, the sound alert system may be adapted to notify the user if the enclosure has been inadvertently left ajar. The sound alert system is preferably activated by the same sensor 12, switch, and power source 16 that operates the light source 14. Furthermore, the sound alert system may be connected to a wireless device in order to alert users in remote locations when their enclosure has been opened or has been left open.

As a person skilled in the art will recognize from the previous detailed description and from the figures and claims, modifications and changes can be made to the preferred embodiments of the invention without departing from the scope of this invention defined in the following claims.

I claim:

1. A system to illuminate an enclosure, comprising:
a sensor to detect the status of an enclosure;
a light source to illuminate the enclosure; and
a housing adapted to protect and contain the light source.

2. The system of claim 1, wherein the sensor is a magnetic sensor, including a magnet adapted to be fixed to a movable portion of the enclosure, and a magnet-sensing device adapted to be mounted to a fixed portion of the enclosure.

3. The system of claim 2, further comprising an installation guide element adapted to ensure proper installation of the system.

4. The system of claim 3, wherein the installation guide includes a first section that temporarily couples to the magnet-sensing device, and a second section that temporarily couples to the magnet.

5. The system of claim 1, wherein the light source is a LED.

6. The system of claim 5, further comprising a circuit board, wherein the LED is manufactured and placed directly on the circuit board.

7. The system of claim 1, wherein the housing includes a first portion adapted to at least temporarily mount to the enclosure and a second portion adapted to selectively connect with the first portion and to generally support a power source, which facilitates removal of the second portion from the enclosure and maintenance or replacement of the power source.

8. The system of claim 7, further comprising an installation guide element adapted to ensure proper installation of the system.

9. The system of claim 8, wherein the installation guide includes a first section that temporarily couples to the first portion of the housing.

10. The system of claim 1, wherein the housing has a low profile shape that generally minimizes the volume of the system and generally minimizes the potential of the system to contact any contents of the enclosures.

11. The system of claim lo, wherein the housing has an aspect ratio (defined as the ratio of the height to the length or width) of less than 1:10.

12. The system of claim 1, further comprising an installation guide element adapted to ensure proper installation of the system.

13. The system of claim 1, further comprising a timing element adapted to shut the system off after a predetermined length of time, which ensures that the light source will not be inadvertently left on.

14. The system of claim 1, further comprising a slow turn-on element adapted to slowly turn-on the light source, which assures a user that the light source is not always on.

15. A system to illuminate an enclosure, comprising:
a sensor to detect the status of an enclosure, wherein the sensor is a magnetic sensor, including a magnet adapted to be fixed to a movable portion of the enclosure, and a magnet-sensing device adapted to be mounted to a fixed portion of the enclosure;
a light source to illuminate the enclosure;
a housing adapted to protect and contain the light source; and
an installation guide element adapted to ensure proper installation of the system, wherein the installation guide includes a first section that temporarily couples to the magnet-sensing device, and a second section that temporarily couples to the magnet.

16. The system of claim 15, wherein the housing includes a first portion adapted to at least temporarily mount to the enclosure and a second portion adapted to selectively connect with the first portion and to generally support the light source and a power source, which facilitates removal of the second portion from the enclosure and maintenance or replacement of the power source.

17. The system of claim 16, further comprising a slow turn-on element adapted to slowly turn-on the light source, which assures a user that the light source is not always on.

18. A system to illuminate an enclosure, comprising:
a sensor to detect the status of an enclosure;
a light source to illuminate the enclosure;
a housing adapted to protect and contain the light source, wherein the housing includes a first portion adapted to at least temporarily mount to the enclosure and a second portion adapted to selectively connect with the first portion and to generally support the light source and a power source, which facilitates removal of the second portion from the enclosure and maintenance or replacement of the power source; and
an installation guide element adapted to ensure proper installation of the system, wherein the installation guide includes a first section that temporarily couples to the first portion of the housing.

19. The system of claim 18, wherein the sensor is a magnetic sensor, including a magnet adapted to be fixed to a movable portion of the enclosure, and a magnet-sensing device adapted to be mounted to a fixed portion of the enclosure.

20. The system of claim 19, further comprising a slow turn-on element adapted to slowly turn-on the light source, which assures a user that the light source is not always on.
